(19) United States
(12) Patent Application Publication
(10) Pub. No.: US 2026/0153548 A1
(43) Pub. Date: Jun. 4, 2026

(54) TEST AND/OR MEASUREMENT SYSTEM AND MEASUREMENT METHOD

(71) Applicant: Rohde & Schwarz GmbH & Co. KG, Muenchen (DE)

(72) Inventor: Christian KUHN, Muenchen (DE)

(21) Appl. No.: 19/361,233

(22) Filed: Oct. 17, 2025

(30) Foreign Application Priority Data
Dec. 2, 2024 (DE) 10 2024 135 629.4

(51) Int. Cl. G01R 29/08

(52) U.S. Cl. CPC G01R 29/0871

(57) ABSTRACT

A device includes a first measurement circuit set up to digitize a first measurement signal to obtain a first digital measurement signal, a signal processing circuit having an average value detector circuit, an effective value detector circuit, and a variance detector circuit. The average value detector circuit is set up to average a first digital baseband signal over a detector interval of the average value detector circuit to obtain a first detector signal. The effective value detector circuit is set up to determine an effective value of the first digital baseband signal over a detector interval of the effective value detector circuit to obtain a second detector signal. The variance detector circuit is set up to determine at least one variance parameter of the first digital baseband signal based on the first detector signal and the second detector signal.

### CROSS-REFERENCE(S) TO RELATED APPLICATION(S)

This application claims priority from German Application No. 10 2024 135 629.4, filed on Dec. 2, 2024, the entire contents of which are disclosed herein in entirety.

### FIELD OF THE DISCLOSURE

Embodiments of the present disclosure generally relate to a test and/or measurement system having a test and/or measurement device. Embodiments of the present disclosure furthermore relate to a measurement method.

### BACKGROUND

In certain types of test and/or measurement devices, it is common to provide detector circuits which process a measured signal from a device under test and generate corresponding measurement data.

Due to increasingly complex measurements, considerable expertise is required to assess how reliable the measurement data provided by the respective detector actually is.

For example, measurements may be performed too briefly or not repeated often enough, even though the measurement data is unreliable.

On the other hand, measurements may be repeated too long or unnecessarily, even though the measurement data is already reliable.

Thus, there is a need for a test and/or measurement system and a measurement method which make it easier to assess the reliability of the measurement data obtained.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a test and/or measurement system having a test and/or measurement device. In an embodiment, the test and/or measurement device has a first port which is connectable to a device under test, wherein the first port is set up to receive a first measurement signal. The test and/or measurement device also comprises a first measurement circuit connected to the first port, wherein the first measurement circuit is set up to digitize the first measurement signal, a first digital measurement signal being thus obtained. The test and/or measurement device further comprises a signal processing circuit, wherein the signal processing circuit has an average value detector circuit, an effective value detector circuit, and a variance detector circuit.

The signal processing circuit is set up to mix the first digital measurement signal into a baseband, a first digital baseband signal being thus obtained. The average value detector circuit is set up to average the first digital baseband signal over a detector interval of the average value detector circuit, a first detector signal being thus obtained. The effective value detector circuit is set up to determine an effective value of the first digital baseband signal over a detector interval of the effective value detector circuit, a second detector signal being thus obtained. The variance detector circuit is set up to determine at least one variance parameter of the first digital baseband signal based on the first detector signal and the second detector signal, wherein the at least one variance parameter is a measure of a deviation of the first digital baseband signal from the average value thereof.

In an embodiment, the effective value is understood to be the root of the sum of squared sample values, i.e., a square mean, which is also referred to as “root mean square”.

In an embodiment, the average value detector circuit and the effective value detector circuit are circuits which are usually provided in test and/or measurement devices.

The present disclosure is based on the finding that the output signals of these two circuits can be reused to determine at least one variance parameter using the variance detector circuit.

The at least one variance parameter can thus be determined in a particularly computationally efficient manner, since it is not necessary to process the complete first measurement signal or the first baseband signal using the variance detector circuit. Instead, the already processed signals, namely the first detector signal and the second detector signal, can be used.

The test and/or measurement system according to embodiments of the present disclosure therefore provides, in a particularly efficient manner, an easily interpretable quantity which represents a measure of the reliability of the measurement data, namely the at least one variance parameter.

If the at least one variance parameter has a large value, this represents a strong fluctuation of the individual measured values around their average value, which may be a sign of unreliable measurement data.

For example, the measurement data may be unreliable due to disturbances and/or systematic errors in the measurement setup.

If, on the other hand, the at least one variance parameter has a small value, this indicates a small fluctuation of the individual measured values around their average value, which may be a sign of reliable measurement data.

In an embodiment, the at least one variance parameter comprises, for example, a variance, a mean square deviation, or a standard deviation. However, the at least one variance parameter may also comprise any other suitable statistical quantity which describes a deviation of the first digital baseband signal from the average value thereof.

In an embodiment, the first measurement signal may be an output signal of the device under test or a signal reflected on the device under test.

In an embodiment, the first measurement signal is a high-frequency signal (HF signal).

According to one aspect of the present disclosure, the signal processing circuit, for example, has a filter unit which is arranged upstream of the average value detector circuit and the effective value detector circuit, for example wherein the filter unit comprises a low-pass filter. The filter unit can be used to filter out unwanted signal components that lie outside the baseband. This ensures that the average value detector circuit and the effective value detector circuit only process the desired signal that lies in the baseband.

In one embodiment, the first measurement circuit has a first mixer circuit and a first digitization circuit, wherein the first mixer circuit is set up to mix the first measurement signal to an intermediate frequency, a first intermediate frequency signal being thus obtained, and wherein the first digitization circuit is set up to digitize the first intermediate frequency signal, the first digital measurement signal being thus obtained. In other words, the first measurement signal is down-mixed to the intermediate frequency by the first mixer circuit and then digitized by the first digitization circuit.

In an embodiment, the first measurement circuit may also have a filter unit, which is for example set up as a low-pass filter. In an embodiment, the filter unit may be arranged between the first mixer circuit and the first digitization circuit.

In an embodiment, the filter unit is, for example, an anti-aliasing filter which removes interfering signal components from the intermediate frequency signal and thus from the first digital measurement signal.

According to a further aspect of the present disclosure, the test and/or measurement system also comprises, for example, a visualization circuit. In an embodiment, the visualization circuit is set up to generate visualization data based on the at least one determined variance parameter, wherein the visualization data comprises a graphical representation of the at least one determined variance parameter and/or a graphical representation of at least one quantity derived from the at least one determined variance parameter. The visualization data can, for example, be displayed on a screen. In this way, a user of the test and/or measurement system can assess particularly quickly whether the measurement data is trustworthy.

In an embodiment, the at least one derived quantity may, for example, be a quantity resulting from mathematical transformations of the at least one determined variance parameter. The mathematical transformations include, for example, linear scaling, logarithmic scaling, normalization based on a defined normalization factor, and/or applying a function to the at least one determined variance parameter.

In an embodiment, the visualization data may also comprise a graphical representation of the first detector signal and/or the second detector signal. The at least one variance parameter and/or the at least one derived quantity can thus be visualized together with the measurement data, which enables particularly rapid identification of critical areas of the measurement data.

In a further embodiment of the present disclosure, the variance detector circuit is set up to determine a time history of the at least one variance parameter. In an embodiment, the at least one variance parameter is thus repeatedly determined by the variance detector circuit, the time history of the at least one variance parameter being thus obtained. The time history of the at least one variance parameter provides a quantity which represents a measure of the reliability of the measurement data over time.

In an embodiment, the visualization data may comprise a graphical representation of the time history of the at least one variance parameter and/or a time history of the at least one quantity derived from the at least one determined variance parameter.

Alternatively or additionally, the visualization data may comprise a numerical value of the at least one variance parameter and/or the at least one derived quantity.

In an embodiment, the numerical value may be determined repeatedly, wherein the visualization data is updated accordingly so that the current numerical value is always displayed. The repeatedly updated numerical value can be used to track whether the at least one variance parameter stabilizes over time.

A further aspect of the present disclosure provides, for example, that the variance detector circuit is set up to determine at least one averaged variance parameter based on the past M detector intervals of the first detector signal and based on the past N detector intervals of the second detector signal, wherein M is a natural number and N is a natural number. In other words, the averaged variance parameter can be determined based on an average value of the first detector signal over the M past detector intervals and/or based on an average value of the second detector signal over the N past detector intervals. Averaging over the M or N detector intervals increases the accuracy of the measurement data, which is typically reflected in a smaller value of the averaged variance parameter compared to the at least one variance parameter.

In this context and in the following, “natural numbers” are understood to be integers greater than zero.

In one embodiment, M is equal to N. The first detector signal and the second detector signal are therefore averaged over the same number of detector intervals.

Alternatively, however, M may be greater than N or N may be greater than M.

In an embodiment, the variance detector circuit is set up to determine the at least one averaged variance parameter based on all past detector intervals of the first detector signal and/or based on all past detector intervals of the second detector signal. Averaging over all past detector intervals results for example small errors in the averaged detector signals, which is typically reflected in a small value of the at least one averaged variance parameter.

In another embodiment of the present disclosure, the variance detector circuit is set up to repeatedly determine the at least one averaged variance parameter. A time history of the at least one averaged variance parameter is thus also obtained. By repeatedly determining the at least one averaged variance parameter, a development of the at least one averaged variance parameter can be analyzed. If the at least one averaged variance parameter becomes smaller over time, this indicates an increase in measurement accuracy. If, on the other hand, the at least one averaged variance parameter becomes larger over time, this indicates a deterioration in measurement accuracy.

For example, the averaged variance parameter can be redetermined when new detector values are provided by the average value detector circuit and/or the effective value detector circuit, i.e., when a new first detector signal and/or a new second detector signal is available.

In an embodiment, the test and/or measurement device may have a second port, wherein the second port is connectable to the device under test. More specifically, the first port and the second port can be connected to different connections of the device under test.

For example, the first port can be connected to a signal output of the device under test and the second port to a signal input of the device under test, or vice versa.

In an embodiment, the second port is different from the first port.

One aspect of the present disclosure provides, for example, that the test and/or measurement device has a second measurement circuit which is connected to the second port. In an embodiment, the second port is set up to receive a second measurement signal. The second measurement circuit is set up to digitize the second measurement signal, a second digital measurement signal being thus obtained, and the signal processing circuit is set up to determine at least one further variance parameter based on the second digital measurement signal. In this embodiment, it is therefore possible to receive two different measurement signals from the device under test and to perform corresponding measurements, wherein at least one variance parameter is determined for each of the two measurement signals, which is a measure of the fluctuation of the corresponding desired signals, i.e., the corresponding digital baseband signals.

In an embodiment, S-parameters of the device under test or other suitable transmission and reflection parameters of the device under test can be measured.

A further aspect of the present disclosure provides, for example, that the test and/or measurement system comprises a signal generator circuit. In an embodiment, the signal generator circuit is arranged to generate a test signal, wherein the first measurement signal corresponds to the test signal which has been processed by the device under test or which has been reflected at the device under test. The signal generator circuit may, for example, be integrated into the test and/or measurement device. However, the signal generator circuit may also be provided separately from the test and/or measurement device.

In an embodiment, the test signal is output via the first port and/or via the second port and is processed by the device under test and/or reflected at the device under test, the first measurement signal and/or the second measurement signal being thus obtained.

According to one embodiment, the test signal is a CW signal. The test signal is therefore a sinusoidal signal which has only one single frequency. Thus, is it possible to measure the properties of the device under test at the frequency of the CW signal by the test signal.

In another embodiment, a frequency of the test signal is constant at least over one detector interval, for example wherein the frequency is constant over a plurality of detector intervals. A plurality of measurement points are thus recorded at the same frequency of the test signal, namely over at least one detector interval, which increases the accuracy of the measurements. The first detector signal and the second detector signal as well as the at least one variance parameter are determined over these several measurement points.

In an embodiment, the signal processing circuit may be set up to drive the signal generator circuit such that a frequency of the first test signal is adjusted. It is thus possible to perform measurements at several different frequencies of the test signal, so that the properties of the device under test can be measured at the different frequencies.

However, the frequency of the test signal always remains constant over at least one detector interval before it is changed again.

In an embodiment, the frequency of the test signal can be varied continuously or gradually over a predefined frequency range, which is also referred to as a “frequency sweep”.

In an embodiment, several measurement points are recorded for each frequency, namely over at least one detector interval.

In an embodiment, the signal processing circuit is set up to drive the signal generator circuit to adjust the frequency if the at least one determined variance parameter or an averaged variance parameter is smaller than a predefined limit value. The frequency is therefore only adjusted as soon as fluctuations in the first digital baseband signal are smaller than a corresponding limit value. This ensures high measurement accuracy at each frequency.

In one embodiment of the present disclosure, the signal processing circuit is set up to determine the at least one variance parameter for a plurality of different frequencies of the test signal. In an embodiment, the at least one variance parameter is determined for each frequency of the test signal. This provides a measure of the reliability of the measurement results for each frequency.

A further aspect of the present disclosure provides, for example, that the test and/or measurement device is a vector network analyzer, a signal analyzer, or a spectrum analyzer. However, the test and/or measurement device may also be set up as any other suitable type of test and/or measurement instrument.

Embodiments of the present disclosure further provide a measurement method. In an embodiment, the measurement method comprises:
receiving a first measurement signal by a first measurement circuit;
digitizing the first measurement signal by the first measurement circuit, a first digital measurement signal being thus obtained;
mixing the first digital measurement signal into a baseband by a signal processing circuit, a first digital baseband signal being thus obtained;
averaging, by an average value detector circuit, the first digital baseband signal over a detector interval of the average value detector circuit, a first detector signal being thus obtained;
determining, by an effective value detector circuit, an effective value of the first digital baseband signal over a detector interval of the effective value detector circuit, a second detector signal being thus obtained; and
determining, by a variance detector circuit, at least one variance parameter of the first digital baseband signal based on the first detector signal and the second detector signal, wherein the at least one variance parameter is a measure of a deviation of the first digital baseband signal from the average value thereof.

Any one of the test and/or measurement systems described above is set up to perform the measurement method according to the present disclosure.

With regard to the advantages and further features of the measurement method, reference is made to the above explanations regarding the test and/or measurement system, which also apply to the measurement method and vice versa.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a test and/or measurement system according to an embodiment of the present disclosure;

FIG. 2 schematically shows an example of a measurement circuit of the test and/or measurement system of FIG. 1;

FIG. 3 schematically shows an example of a signal processing circuit of the test and/or measurement system of FIG. 1;

FIG. 4 shows an example of a flowchart of a measurement method according to an embodiment of the present disclosure; and

FIG. 5 shows a diagram with a graphical representation of a determined variance parameter.

### DETAILED DESCRIPTION

The detailed description set forth below in connection with the appended drawings is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

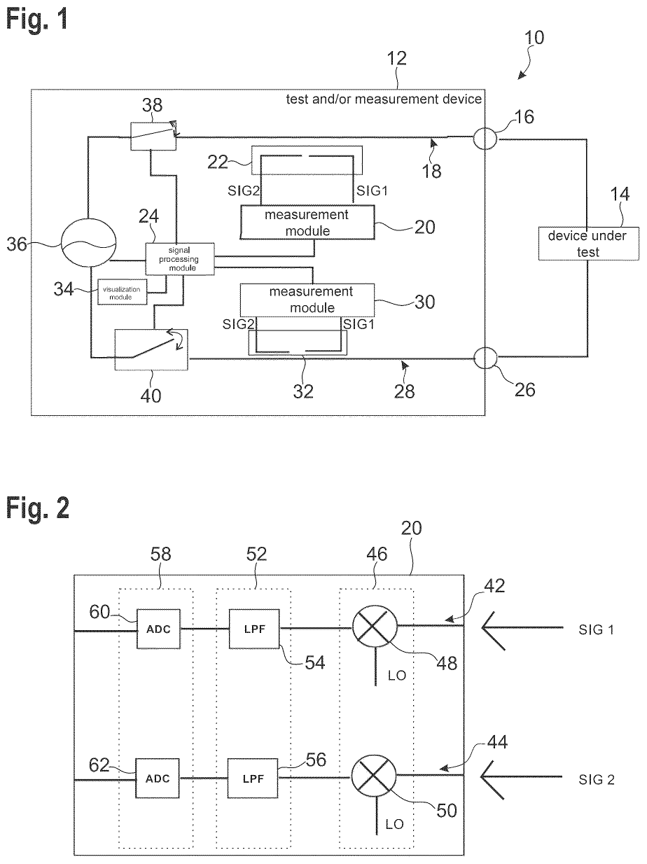

FIG. 1 schematically shows a test and/or measurement system 10 that includes a test and/or measurement device 12 and a device under test 14. In general terms, the test and/or measurement system 10, or the test and/or measurement device 12, is set up to perform measurements on the device under test 14 to verify a correct functionality of the device under test 14.

For example, the test and/or measurement device 12 is a vector network analyzer, a signal analyzer, or a spectrum analyzer. However, the test and/or measurement device 12 can also be set up as any other suitable type of test and/or measurement instrument.

The device under test 14 is an electronic device set up to generate and/or process HF signals. For example, the device under test 14 is an amplifier, a mixer, a filter, a communication circuit for data communication, or any other electronic device set up to generate and/or process HF signals.

As shown in FIG. 1, the test and/or measurement device 12 has a first port 16 which is connected to the device under test 14. For example, the first port 16 is connected to the device under test 14 via a suitable cable.

The test and/or measurement device 12 comprises a first signal path 18 which is connected to the first port 16. The test and/or measurement device 12 further comprises a first measurement circuit 20, which is coupled to the first signal path 18 in a signal-transmitting manner. In the exemplary embodiment of FIG. 1, the first signal path 18 is connected to the first measurement circuit 20 via a first coupling element 22.

In general terms, the first coupling element 22 is set up to transmit forward signals, i.e., signals propagating in the direction of the first port 16, and/or backward signals, i.e., signals propagating away from the first port 16, to the first measurement circuit 20. For example, the first coupling element 22 is a directional coupler, a power divider, a power combiner, or another suitable component.

The test and/or measurement device 12 also has a signal processing circuit 24, which is connected to the first measurement circuit 20.

In the example embodiment of the test and/or measurement system shown in FIG. 1, the test and/or measurement device 12 further comprises a second port 26, which is connected to the device under test 14, for example via a suitable cable. The first port 16 and the second port 26 are connected to different connections of the device under test 14, for example to a signal input and a signal output of the device under test 14.

The test and/or measurement device 12 further comprises a second signal path 28, which is connected to the second port 26. The test and/or measurement device 12 also has a second measurement circuit 30, which is coupled to the second signal path 28 in a signal-transmitting manner. In the example embodiment of FIG. 1, the second signal path 28 is connected to the second measurement circuit 30 via a second coupling element 32.

In general terms, the second coupling element 32 is set up to transmit forward signals, i.e., signals propagating in the direction of the second port 26, and/or backward signals, i.e., signals propagating away from the second port 26, to the second measurement circuit 30. For example, the second coupling element 32 is a directional coupler, a power divider, a power combiner, or another suitable component. The second measurement circuit 30 is also connected to the signal processing circuit 24.

In an embodiment, the test and/or measurement device 12 may also comprise a visualization circuit 34 connected to the signal processing circuit 24. In addition, the test and/or measurement device 12 in the embodiment shown in FIG. 1 has a signal generator circuit 36 which is set up to generate a test signal.

The generated test signal can be selectively output to the first port 16 and thus to the device under test 14 via a first switching element 38 arranged in the first signal path 18. In addition, the generated test signal can be selectively output to the second port 26 and thus to the device under test 16 via a second switching element 40 arranged in the second signal path 28.

It should be noted that the signal generator circuit 36 can also be set up separately from the test and/or measurement device 12.

FIG. 2 schematically shows an example of the first measurement circuit 20 in more detail. As shown in FIG. 2, the first measurement circuit 20 has a first measurement signal path 42 which is set up to process a signal (“SIG1”) running forward in the first signal path 18. The first measurement circuit 20 also has a second measurement signal path 44, which is set up to process a signal (“SIG2”) running backwards in the first signal path 18.

The first measurement circuit 20 comprises a first mixer circuit 46 having a first mixer unit 48 and a second mixer unit 50. The first mixer unit 48 is assigned to the first measurement signal path 42, while the second mixer unit 50 is assigned to the second measurement signal path 44.

The first measurement circuit 20 also comprises a first filter circuit 52 including a first low-pass filter 54, which is assigned to the first measurement signal path 42, and a second low-pass filter 56, which is assigned to the second measurement signal path 44. The first mixer circuit 46 is arranged upstream of the first filter circuit 52.

The first mixer circuit 20 also comprises a first digitization circuit 58 having a first analog-to-digital converter (ADC) 60 and a second ADC 62. The first ADC 60 is assigned to the first measurement signal path 42, while the second ADC 60 is assigned to the second measurement signal path. The first filter circuit 52 is arranged upstream of the first digitization circuit 58.

The second measurement circuit 30 is structured analogously to the first measurement circuit 20 and is therefore not described in further detail.

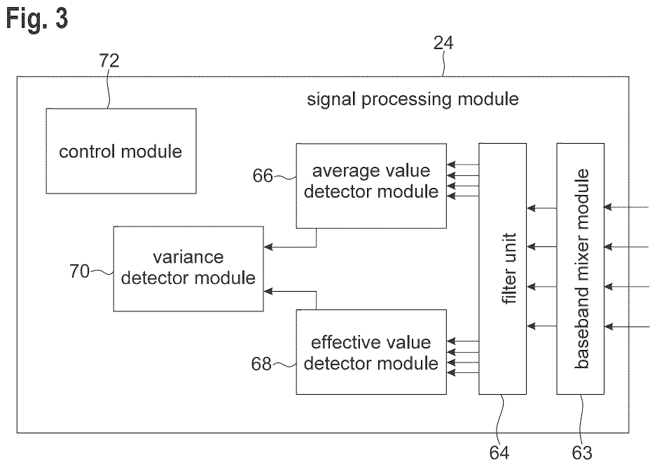

FIG. 3 schematically shows an example of the signal processing circuit 24 in more detail. As shown in FIG. 3, the signal processing circuit 24 comprises a baseband mixer circuit 63, which is connected to the first measurement circuit 20 and to the second measurement circuit 30. The signal processing circuit 24 also has a filter unit 64 which is connected to the baseband mixer circuit 63, wherein the filter unit 64 is provided downstream of the baseband mixer circuit 63. The filter unit 64 is, for example, a filter with finite impulse response, also known as a “finite impulse response (FIR) filter.” For example, the filter unit 64 comprises a low-pass filter or is set up as a low-pass filter.

The signal processing circuit 24 further comprises an average value detector circuit 66 and an effective value detector circuit 68, which are each arranged downstream of the filter unit 64. The average value detector circuit 66 and the effective value detector circuit 68 are arranged in parallel to each other.

The signal processing circuit 24 also has a variance detector circuit 70, which is connected to both the average value detector circuit 66 and the effective value detector circuit 68.

The signal processing circuit 24 may also comprise a control circuit 72 which is set up to control the signal generator circuit 36, the first switching element 38 and/or the second switching element 40.

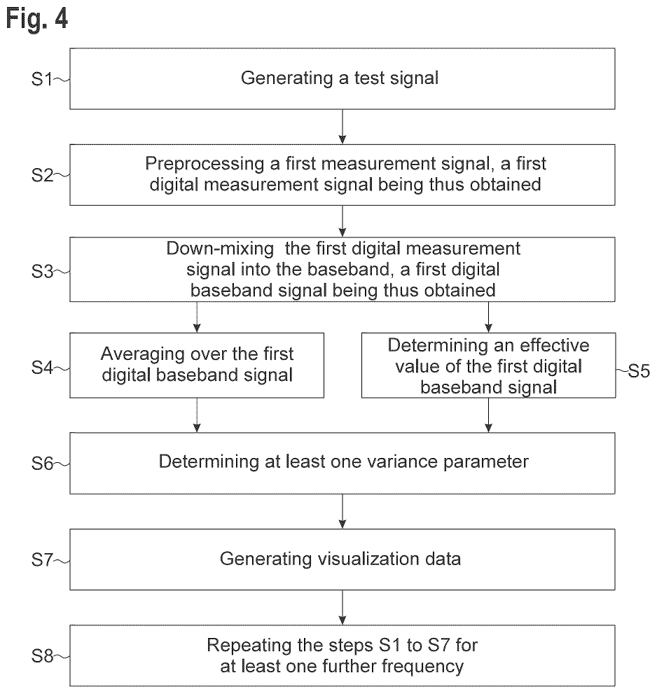

The test and/or measurement system 10, or more precisely the test and/or measurement device 12, is set up to perform a measurement method, an example of which will be described below with reference to FIG. 4.

A test signal is generated by the signal generator circuit 36 (step S1).

The test signal is a CW signal having a defined frequency. The test signal is output to the device under test 14 via the first port 16 and/or via the second port 26. In addition, the test signal is transmitted from the first coupling element 22 to the first measurement circuit 20. Alternatively or additionally, the test signal is transmitted to the second measurement circuit 30 via the second coupling element 32. The test signal is processed by the device under test 14 and/or reflected at the device under test 14, a corresponding measurement signal being thus obtained.

A case is discussed below by way of example, in which the test signal is output to the device under test 14 via the second port 26 and processed by the device under test 14, resulting in a first measurement signal which is received via the first port 16. However, the following explanations also apply accordingly to reflection measurements via the first port 16, reflection measurements via the second port 26, and transmission measurements in the opposite direction.

The first measurement signal is transmitted from the first coupling element 22 to the first measurement circuit 20.

The test signal and the first measurement signal are preprocessed by the first measurement circuit 20 (step S2).

More specifically, the first measurement signal is down-mixed to an intermediate frequency by the second mixer unit 50, a first intermediate frequency signal being thus obtained. The first intermediate frequency signal is then filtered by the second low-pass filter 56 and transmitted to the second ADC 62. The first intermediate frequency signal is digitized by the second ADC 62, a first digital measurement signal being thus obtained. The first digital measurement signal is forwarded to the signal processing circuit 24.

Analogous to the first measurement signal, the test signal is processed by the first mixer unit 48, the first low-pass filter 54, and the first ADC 60, a digital test signal being thus obtained. The digital test signal is forwarded to the signal processing circuit 24.

The first digital measurement signal and the digital test signal are each mixed into a baseband by the baseband mixer circuit 63, a first digital baseband signal and a digital baseband test signal, respectively, being thus obtained (step S3).

The first digital baseband signal and the digital baseband test signal are then filtered by the filter unit 64 to remove unwanted signal components, signal components outside the baseband being for example filtered out. The first digital baseband signal and the digital baseband test signal are forwarded to both the average value detector circuit 66 and the effective value detector circuit 68.

The first digital baseband signal is averaged over a detector interval of the average value detector circuit 66 by the average value detector circuit 66, a first detector signal being thus obtained (step S4).

The average value detector circuit 66 is based on the mathematical model described below.

After the filter unit 64, the first digital baseband signal has the following form:

$${y}_{n} = {\sum }_{k = 0}^{K - 1} {h}_{k} ( s + {w}_{n - k} )$$

Here, the desired signal s=A·e^{iφ} in the baseband is a complex constant, wherein A and φ can be determined from a comparison of the first digital baseband signal with the baseband test signal.

Furthermore, the desired signal s is superimposed with a noise signal w. The noise signal w is based on an additive normally distributed noise process with a normal distribution

$$ℵ ( 0 ; {σ}_{w}^{2} ) .$$

The individual noise values wₙ are assumed to be uncorrelated.

hₖ denotes the filter coefficients of the filter unit 64.

For the first digital baseband signal, this results in

$${y}_{n} = {G}_{1} \cdot s + {\overline{w}}_{n} ,$$

with the DC component amplification

$${G}_{1} = {\sum }_{k = 0}^{K - 1} {h}_{k}$$

of the filter unit 64 and the noise process shifted to the filter output

$${\overline{w}}_{n} = {\sum }_{k = 0}^{K - 1} {h}_{k} {w}_{n - k} .$$

The noise process is normally distributed with

$$ℵ ( 0 ; {G}_{2} \cdot {σ}_{w}^{2} )$$

and has correlated sample values. The variance is amplified by

$${G}_{2} = {\sum }_{k = 0}^{K - 1} {\vert {h}_{k} \vert}^{2} .$$

However, if a decimation R of the filter unit 64 is selected such that it is greater than or equal to the filter length K of the filter unit 64, uncorrelated noise values having the aforementioned normal distribution are obtained.

On the decimated time scale n=m·R, this results in the model

$${\tilde{y}}_{m} = {G}_{1} \cdot s + {\tilde{w}}_{m}$$

with \tilde{y}m=y_{m·R} and \tilde{w}ₘ=w_{m·R}.

The average value detector circuit 66 first performs an accumulation over the detector interval having the length D as follows:

$${a}_{l} = {\sum }_{d = 0}^{D - 1} {\tilde{y}}_{D \cdot l + d} .$$

Normalization with the detector length D results in the following average value

$${a}_{l}^{′} = \frac{1}{D} {a}_{l} = {G}_{1} \cdot s + \frac{1}{D} {\sum }_{d = 0}^{D - 1} {\tilde{w}}_{D \cdot l + d} .$$

The first detector signal comprises this average value.

Using the effective value detector circuit 68, an effective value of the first digital baseband signal is determined over a detector interval of the effective value detector circuit 68, a second detector signal being thus obtained (step S5).

To this end, the following accumulation is performed by the effective value detector circuit 68:

$${ρ}_{l} = {\sum }_{d = 0}^{D - 1} {\vert {\tilde{y}}_{D \cdot l + d} \vert}^{2}$$

By normalizing with the detector length D, the following average value of the squares of the absolute values is obtained:

$${ρ}_{l}^{′} = \frac{1}{D} {ρ}_{l} = \frac{1}{D} {\sum }_{d = 0}^{D - 1} {\vert {G}_{1} \cdot s + {\tilde{w}}_{D \cdot l + d} \vert}^{2}$$

The root of the average value of the absolute value squares results in the effective value, the second detector signal comprising the effective value.

Based on the first detector signal and the second detector signal, at least one variance parameter is determined by the variance detector circuit 70 (step S6).

In general, the at least one variance parameter is a measure of a deviation of the first digital baseband signal from the average value thereof.

More specifically, for example, the variance

$${\hat{σ}}_{l}^{2}$$

of the inter output values ýₘ over a single detector interval is obtained by the unbiased estimate

$${\hat{σ}}_{l}^{2} = \frac{1}{D - 1} {\sum }_{d = 0}^{D - 1} {\vert {\tilde{y}}_{D \cdot l + d} - {a}_{l}^{′} \vert}^{2} .$$

By resolving the absolute difference, this relationship can be transformed to

$${\hat{σ}}_{l}^{2} = \frac{1}{D - 1} {\sum }_{d = 0}^{D - 1} \vert {\tilde{y}}_{D \cdot l + d} \vert - \frac{D}{D - 1} {\vert {a}_{l}^{′} \vert}^{2} .$$

This gives the variance based on the first detector signal and the second detector signal as

$${\hat{σ}}_{l}^{2} = \frac{1}{D - 1} {ρ}_{l} - \frac{1}{( D - 1 ) \cdot D} {\vert {a}_{l} \vert}^{2} .$$

The variance

$${\hat{σ}}_{l}^{2}$$

can therefore be determined from the first detector signal and the second detector signal.

It should be noted that instead of the variance, another suitable statistical quantity can also be determined, a mean square deviation or a standard deviation, for example.

The first detector signal, the second detector signal, and/or the at least one determined variance parameter are transmitted to the visualization circuit 34.

The steps S4 to S6 described above are each based on a detector interval having the length D.

It should be noted that these steps can be performed repeatedly, a time history of the first detector signal, the second detector signal, and/or the at least one variance parameter being thus obtained.

For example, the steps S4 to S6 are performed for a plurality of detector intervals, for example for successive detector intervals.

Alternatively or additionally, averaging can be performed over several detector intervals in steps S4 to S6.

For the averaged first detector signal, this results in

$${a}_{l}^{′′} = \frac{1}{D \cdot ( l + 1 )} {\sum }_{λ = 0}^{l} {a}_{λ} .$$

In this example, averaging is performed over all previous l detector intervals. However, it should be noted that averaging can also be performed over the last M detector intervals, for example as a running average.

For the averaged second detector signal, this results in

$${ρ}_{l}^{′′} = \frac{1}{D \cdot ( l + 1 )} {\sum }_{λ = 0}^{l} {ρ}_{λ} .$$

Here, too, averaging was calculated over all previous l detector intervals. However, it should be noted that the averaging can also be performed over the last N detector intervals, for example as a running average.

For the at least one variance parameter, averaging over the previous l detector intervals results in at least one averaged variance parameter according to

$${\hat{σ}}_{l}^{′′2} = \frac{1}{D \cdot ( l + 1 ) - 1} {\sum }_{λ = 0}^{l} {ρ}_{λ} - \frac{1}{( D \cdot ( l + 1 ) - 1 ) \cdot D \cdot ( l + 1 )} {\vert {a}_{l} \vert}^{2} .$$

It should be noted that the at least one variance parameter can be determined analogously based on the last M detector intervals of the first detector signal and based on the last N detector intervals of the second detector signal.

In an embodiment, N=M.

It has been shown that the at least one averaged variance parameter has the expected value

$$E \{ {\hat{σ}}_{l}^{′′2} \} = {G}_{2} {σ}_{w}^{2}$$

regardless of the observation duration and is therefore unbiased.

The visualization circuit 34 generates visualization data, wherein the visualization data comprises a graphical representation of the first detector signal, a graphical representation of the second detector signal, a graphical representation of the at least one variance parameter, a graphical representation of the at least one averaged variance parameter, and/or a graphical representation of at least one quantity derived from the at least one determined variance parameter (step S7).

The visualization data can, for example, be displayed on a screen of the test and/or measurement device 12 or on a screen connected to the test and/or measurement device 12.

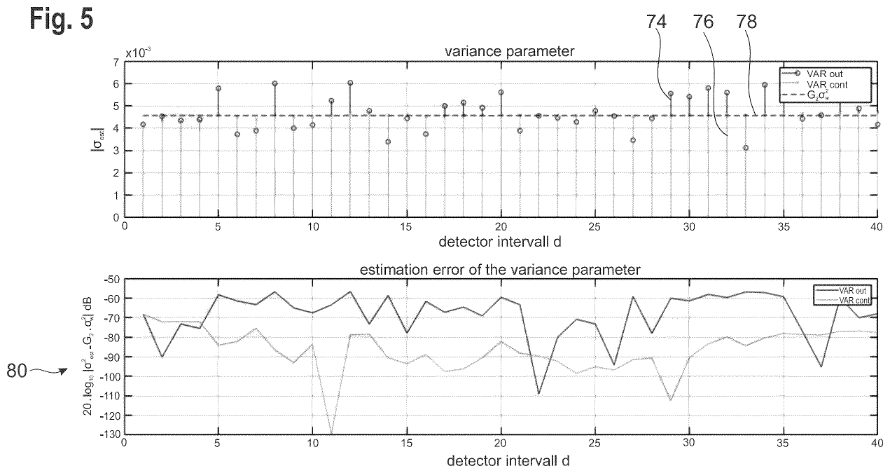

An example of such a visualization is shown in FIG. 5, wherein the visualization data comprises a graphical representation 74 of the time history of the at least one variance parameter and a graphical representation 76 of the time history of the at least one averaged variance parameter.

The time axis is represented by the number of detector intervals (“detector interval d”). For illustrative purposes, an ideal value 78 (i.e., a correct value) of the at least one variance parameter is also plotted in the diagram of FIG. 5. In addition, FIG. 5 also shows an error graph 80, which represents an error of the respective values, i.e., a deviation from the ideal value 78.

It is clearly apparent that averaging over a plurality of detector intervals can significantly improve the accuracy of the at least one variance parameter.

The steps S1 to S7 described above are performed at a single, constant frequency of the test signal. The frequency of the test signal is therefore constant over several detector intervals.

The steps S1 to S7 can be repeated for at least one further frequency of the test signal (step S8). More precisely, the steps S1 to S7 can be repeated for several frequencies. The frequency of the test signal can be varied continuously or gradually over a predefined frequency range.

In an embodiment, the signal generator circuit 36 can be automatically controlled by the control circuit 72 to adjust the frequency of the test signal. For example, the frequency of the test signal is adjusted as soon as the at least one determined variance parameter and/or the at least one averaged variance parameter is/are smaller than a predefined limit value.

It should be noted that the steps of the measurement method have only been explained for the first measurement signal, which is processed by the first measurement circuit 20. However, the steps described above can also be performed for a second measurement signal processed by the second measurement circuit 30.

In this case, at least one further variance parameter and/or at least one further averaged variance parameter is determined by the signal processing circuit in a manner analogous to the above descriptions.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the system 10, etc., referenced above include circuitry programmed to carry out one or more steps of any of the methods disclosed herein. In an embodiment, one or more computer-readable media associated with or accessible by such circuitry contains computer readable instructions embodied thereon that, when executed by such circuitry, cause the component or circuitry to perform one or more steps of any of the methods disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuitry disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A test and/or measurement system comprising:
a test and/or measurement device, the test and/or measurement device including
a first port which is connectable to a device under test, wherein the first port is set up to receive a first measurement signal,
a first measurement circuit connected to the first port, wherein the first measurement circuit is set up to digitize the first measurement signal, a first digital measurement signal being thus obtained, and
a signal processing circuit, wherein the signal processing circuit has an average value detector circuit, an effective value detector circuit, and a variance detector circuit,
wherein the signal processing circuit is set up to mix the first digital measurement signal into a baseband, a first digital baseband signal being thus obtained,
wherein the average value detector circuit is set up to average the first digital baseband signal over a detector interval of the average value detector circuit, a first detector signal being thus obtained,
wherein the effective value detector circuit is set up to determine an effective value of the first digital baseband signal over a detector interval of the effective value detector circuit, a second detector signal being thus obtained, and
wherein the variance detector circuit is set up to determine at least one variance parameter of the first digital baseband signal based on the first detector signal and the second detector signal, wherein the at least one variance parameter is a measure of a deviation of the first digital baseband signal from the average value thereof.

2. The test and/or measurement system according to claim 1, wherein the signal processing circuit comprises a filter unit arranged upstream of the average value detector circuit and the effective value detector circuit.

3. The test and/or measurement system according to claim 2, wherein the filter unit comprises a low-pass filter.

4. The test and/or measurement system according to claim 1, wherein the first measurement circuit comprises a first mixer circuit and a first digitization circuit, wherein the first mixer circuit is set up to mix the first measurement signal to an intermediate frequency, a first intermediate frequency signal being thus obtained, and wherein the first digitization circuit is set up to digitize the first intermediate frequency signal, the first digital measurement signal being thus obtained.

5. The test and/or measurement system according to claim 1, further comprising a visualization circuit, wherein the visualization circuit is set up to generate visualization data based on the at least one determined variance parameter, wherein the visualization data comprises a graphical representation of the at least one determined variance parameter and/or a graphical representation of at least one quantity derived from the at least one determined variance parameter.

6. The test and/or measurement system according to claim 1, wherein the variance detector circuit is set up to determine a time history of the at least one variance parameter.

7. The test and/or measurement system according to claim 1, wherein the variance detector circuit is set up to determine at least one averaged variance parameter based on the past M detector intervals of the first detector signal and based on the past N detector intervals of the second detector signal, wherein Mis a natural number and wherein N is a natural number.

8. The test and/or measurement system according to claim 7, wherein M is equal to N.

9. The test and/or measurement system according to claim 7, wherein the variance detector circuit is set up to determine the at least one averaged variance parameter based on all past detector intervals of the first detector signal and/or based on all past detector intervals of the second detector signal.

10. The test and/or measurement system according to claim 7, wherein the variance detector circuit is set up to repeatedly determine the at least one averaged variance parameter.

11. The test and/or measurement system according to claim 1, wherein the test and/or measurement device has a second port, wherein the second port is connectable to the device under test.

12. The test and/or measurement system according to claim 11, wherein the test and/or measurement device has a second measurement circuit which is connected to the second port, wherein the second port is set up to receive a second measurement signal, wherein the second measurement circuit is set up to digitize the second measurement signal, a second digital measurement signal being thus obtained, and wherein the signal processing circuit is set up to determine at least one further variance parameter based on the second digital measurement signal.

13. The test and/or measurement system according to claim 1, further comprising a signal generator circuit, wherein the signal generator circuit is set up to generate a test signal, wherein the first measurement signal corresponds to the test signal which has been processed by the device under test or which has been reflected at the device under test.

14. The test and/or measurement system according to claim 13, wherein the test signal is a CW signal.

15. The test and/or measurement system according to claim 13, wherein a frequency of the test signal is constant at least over a detector interval.

16. The test and/or measurement system according to claim 13, wherein the signal processing circuit is set up to drive the signal generator circuit such that a frequency of the first test signal is adjusted.

17. The test and/or measurement system according to claim 16, wherein the signal processing circuit is set up to drive the signal generator circuit to adjust the frequency if the at least one determined variance parameter or an averaged variance parameter is smaller than a predefined limit value.

18. The test and/or measurement system according to claim 16, wherein the signal processing circuit is set up to determine the at least one variance parameter for a plurality of different frequencies of the test signal.

19. The test and/or measurement system according to claim 1, wherein the test and/or measurement device is a vector network analyzer, a signal analyzer, or a spectrum analyzer.

20. A measurement method, comprising:
receiving a first measurement signal by a first measurement circuit;
digitizing the first measurement signal by the first measurement circuit, a first digital measurement signal being thus obtained;
mixing the first digital measurement signal into a baseband by a signal processing circuit, a first digital baseband signal being thus obtained;
averaging, by an average value detector circuit, the first digital baseband signal over a detector interval of the average value detector circuit, a first detector signal being thus obtained;
determining, by an effective value detector circuit, an effective value of the first digital baseband signal over a detector interval of the effective value detector circuit, a second detector signal being thus obtained; and
determining, by a variance detector circuit, at least one variance parameter of the first digital baseband signal based on the first detector signal and the second detector signal, wherein the at least one variance parameter is a measure of a deviation of the first digital baseband signal from the average value thereof.
